(19) United States
(12) Patent Application Publication
(10) Pub. No.: US 2026/0152387 A1
(43) Pub. Date: Jun. 4, 2026

(54) MICROELECTROMECHANICAL ARRAY

(71) Applicant: ZILLTEK TECHNOLOGY CORP., Hsinchu City (TW)

(72) Inventors: JEN-YI CHEN, Hsinchu City (TW); CHIH-CHANG HOU, Hsinchu City (TW); KAI-YU JIANG, Hsinchu City (TW)

(21) Appl. No.: 18/965,031

(22) Filed: Dec. 2, 2024

(51) Int. Cl. B81B 7/04

(52) U.S. Cl. CPC B81B 7/04; B81B 2201/0271; B81B 2203/0154; B81B 2203/0307; B81B 2203/04

(57) ABSTRACT

A microelectromechanical array includes a substrate, a plurality of first ring elements, a plurality of second ring elements, and a plurality of electrodes. The substrate has a plurality of anchor pieces. The first ring elements include a plurality of first ring portions and a plurality of first coupling segments. The first ring elements are spaced apart from the substrate. The first coupling segments are connected to the first ring portions, so as to jointly have a node. Each of the second ring elements includes a plurality of second ring portions and a plurality of second coupling segments. The phases of each of second ring portions and the phases of each of the first ring portions are opposite. The electrodes are disposed on the substrate. Each of the electrodes is surrounded by any one of the first ring portions or the second ring portions, without coming in contact therewith.

### FIELD OF THE DISCLOSURE

The present disclosure relates to an array, and more particularly to a microelectromechanical array.

### BACKGROUND OF THE DISCLOSURE

A conventional microelectromechanical array includes two rings, two inner electrodes, two outer electrodes, and a connector. Two ends of the connector are respectively connected to the two rings. The two inner electrodes are surrounded by the two rings, respectively. The two rings are surrounded by the two outer electrodes, respectively. Each of the two outer electrodes has an escape opening that passes through the connector. Accordingly, the two rings of the conventional microelectromechanical array operate in same phase and can form a differential pair through the two outer electrodes and the two inner electrodes, so as to perform resonance work.

However, the signal strength of conventional microelectromechanical arrays is determined based on a total capacitance of the two rings to the two outer electrodes and the two inner electrodes, and capacitance values of the two outer electrodes and the two inner electrodes relative to the ring need to be equal to form the differential pair. Therefore, when calculating the capacitance between the two outer electrodes and the two rings, the escape opening must also be deducted, making the manufacturing process of the conventional microelectromechanical array less convenient.

In addition, when the conventional microelectromechanical array is in operation, the configurations of the two outer electrodes and the two inner electrodes cannot be exactly same to ensure that the capacitance changes are equal. Moreover, the escape opening makes connecting more rings in series through the two outer electrodes challenging, limiting the formation of larger arrays and hindering the improvement of signal performance, such that the performance of the conventional microelectromechanical arrays is difficult to be enhanced.

### SUMMARY OF THE DISCLOSURE

In response to the above-referenced technical inadequacies, the present disclosure provides a microelectromechanical array.

In order to solve the above-mentioned problems, one of the technical aspects adopted by the present disclosure is to provide a microelectromechanical array. The microelectromechanical array includes a substrate, a plurality of first ring elements, a plurality of second ring elements, and a plurality of electrodes. The substrate includes a plurality of anchor pieces. The first ring elements are disposed on the anchor pieces. The first ring elements are spaced apart from the substrate, and include a plurality of first ring portions and a plurality of first coupling segments. The first coupling segments are connected to the first ring portions, so as to jointly have a node. Each of the first ring portions has a first phase. The second ring elements include a plurality of second ring portions and a plurality of second coupling segments. The second ring portions are connected to the first ring portions through the second coupling segments, and each of the second ring portions has a second phase that is opposite to the first phase. The electrodes are disposed on the substrate. Each of the electrodes is surrounded by any of the first ring portions or any of the second ring portions, without coming in contact therewith.

In order to solve the above-mentioned problems, another one of the technical aspects adopted by the present disclosure is to provide a microelectromechanical array. The microelectromechanical array includes a substrate, a plurality of first ring elements, a plurality of second ring elements, and a plurality of electrodes. The substrate includes a plurality of anchor pieces. The first ring elements are disposed on the anchor pieces. The first ring elements are spaced apart from the substrate, and include a plurality of first ring portions and a plurality of first coupling segments. Each of the first coupling segments is connected to one of the first ring portions, so as to jointly have a node. Each of the first ring portions has a first phase. The second ring elements include a plurality of second ring portions and a plurality of second coupling segments. The second ring portions are connected to the first ring portions through the second coupling segments, and each of the second ring portions has a second phase that is opposite to the first phase. The electrodes are disposed on the substrate. Each of the electrodes is surrounded by any of the first ring portions or any of the second ring portions, without coming in contact therewith.

Therefore, in the microelectromechanical array provided by the present disclosure, by virtue of “the first coupling segments being connected to the first ring portions, so as to jointly have a node, and each of the first ring portions having a first phase,” and “the second ring portions being connected to the first ring portions through the second coupling segments, and each of the second ring portions having a second phase that is opposite to the first phase,” the microelectromechanical array can easily calculate the capacitances of each of the first ring elements and the second ring elements, so as to allow the microelectromechanical array to be easily fabricated.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic partially planar view of a microelectromechanical array according to a first embodiment of the present disclosure;

FIG. 2 is a schematic partially planar view showing the microelectromechanical array performing expansion and contraction movements according to the first embodiment of the present disclosure;

FIG. 3 is a schematic partially planar view of the microelectromechanical array according to the first embodiment of the present disclosure in another implementation;

FIG. 4 is a schematic partially planar view of the microelectromechanical array according to the first embodiment of the present disclosure in yet another implementation;

FIG. 5 is a schematic partially planar view of the microelectromechanical array according to the first embodiment of the present disclosure in still another implementation;

FIG. 6 is a schematic partially planar view showing the microelectromechanical array of FIG. 5 performing expansion and contraction movements;

FIG. 7 is a schematic partially planar view of the microelectromechanical array according to the first embodiment of the present disclosure in still yet another implementation;

FIG. 8 is a schematic partially planar view of the microelectromechanical array according to the first embodiment of the present disclosure in a further implementation;

FIG. 9 is a schematic partially planar view of the microelectromechanical array according to a second embodiment of the present disclosure;

FIG. 10 is a schematic partially planar view showing the microelectromechanical array of FIG. 9 increasing in quantity thereof;

FIG. 11 is a schematic partially planar view showing the microelectromechanical array of FIG. 1 increasing in quantity thereof;

FIG. 12 is a schematic partially planar view showing the microelectromechanical array of FIG. 3 increasing in quantity thereof;

FIG. 13 is a schematic partially planar view showing the microelectromechanical array of FIG. 4 increasing in quantity thereof; and

FIG. 14 is a schematic partially planar view showing the microelectromechanical array of FIG. 5 increasing in quantity thereof.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

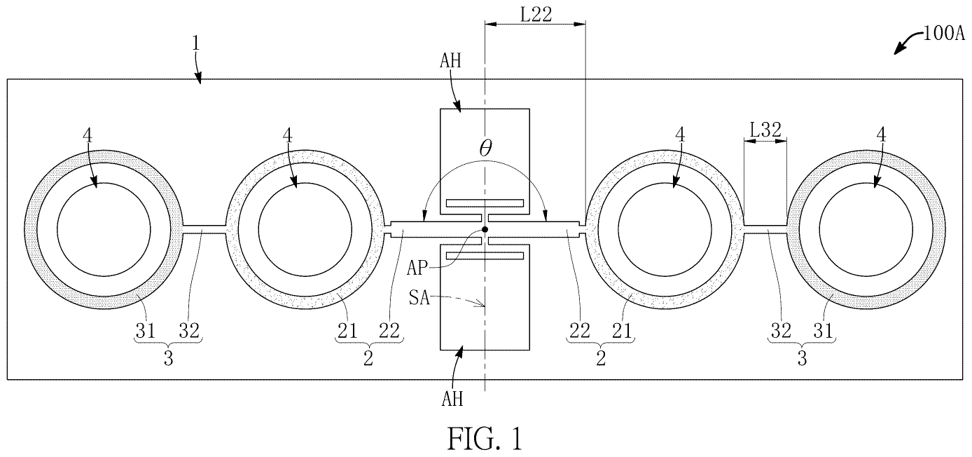

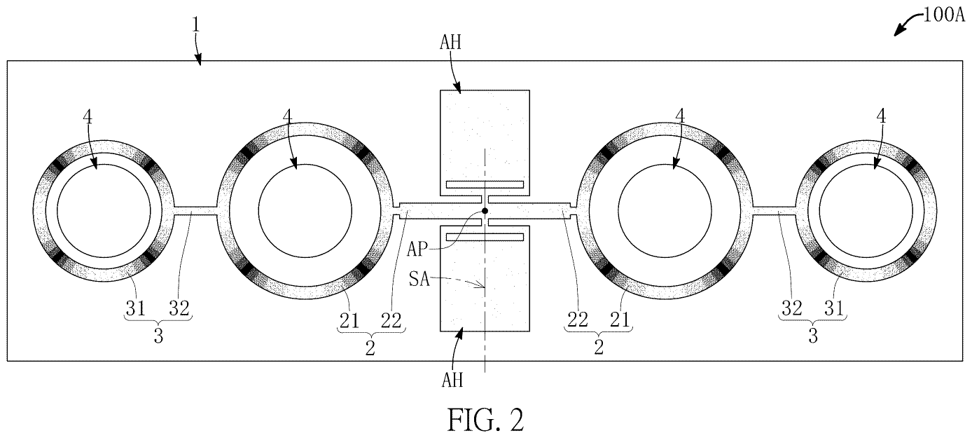

Referring to FIG. 1 to FIG. 8, a first embodiment of the present disclosure provides a microelectromechanical array 100. As shown in FIG. 1 and FIG. 2, the microelectromechanical array 100 includes a substrate 1, and a plurality of first ring elements 2, a plurality of second ring elements 3, and a plurality of electrodes 4 that are disposed on the substrate 1. The following description describes the structure and connection relation of each component of the microelectromechanical array 100.

Referring to FIG. 1 and FIG. 2, the substrate 1 in the present embodiment is a silicon substrate, and has a plurality of anchor pieces AH. The first ring elements 2 are spaced apart on the substrate 1 through the anchor pieces AH, meaning that the first ring elements 2 do not make direct contact with the substrate 1.

Specifically, the first ring elements 2 in the present embodiment can be conductors, and includes a plurality of first ring portions 21 and a plurality of first coupling segments 22. The first coupling segments 22 are connected to the first ring portions 21, and a common position of the first coupling segments 22 forms a node AP located at a center of the first ring portions 21. It can be understood as a position of the node AP where the two adjacent first ring portions 21 offset each other (or have the smallest influence) when they expand or contract.

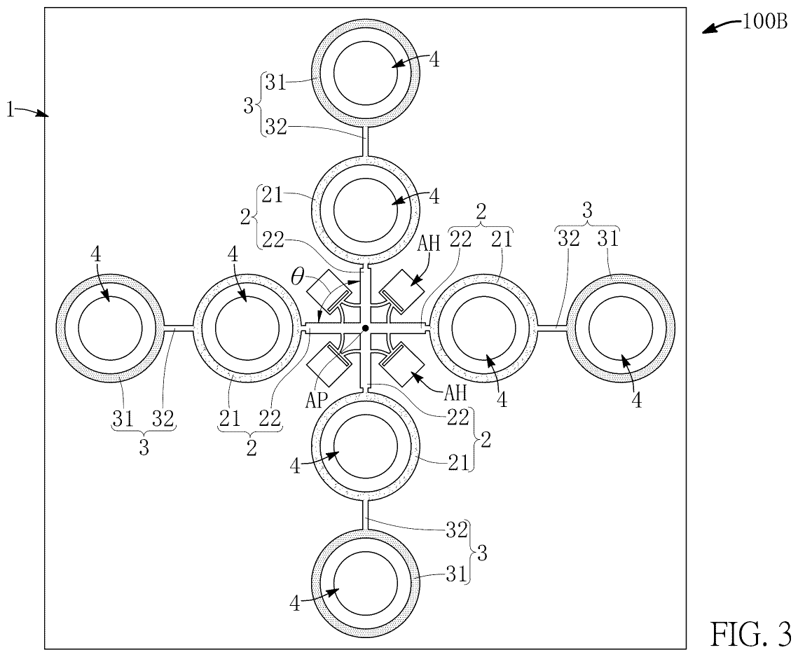

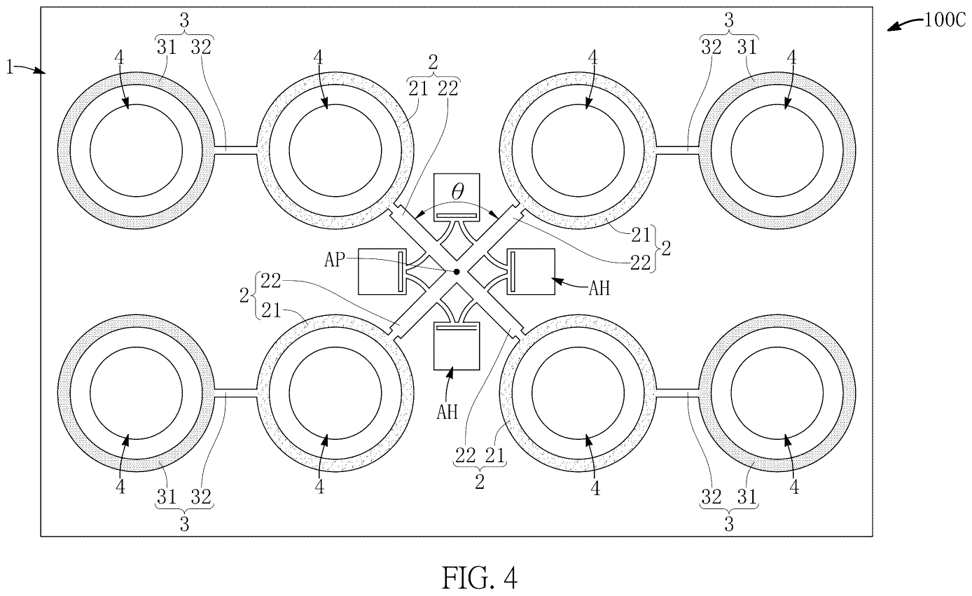

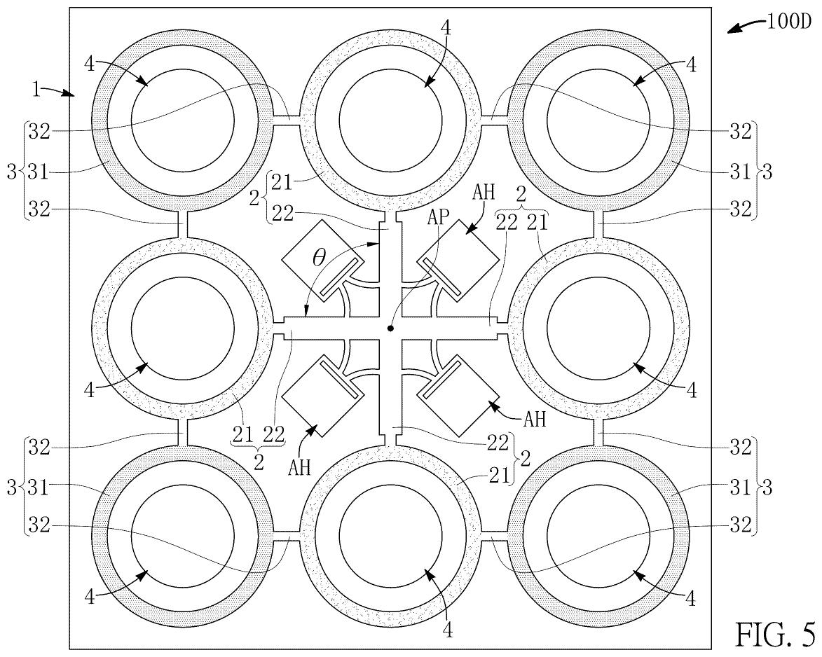

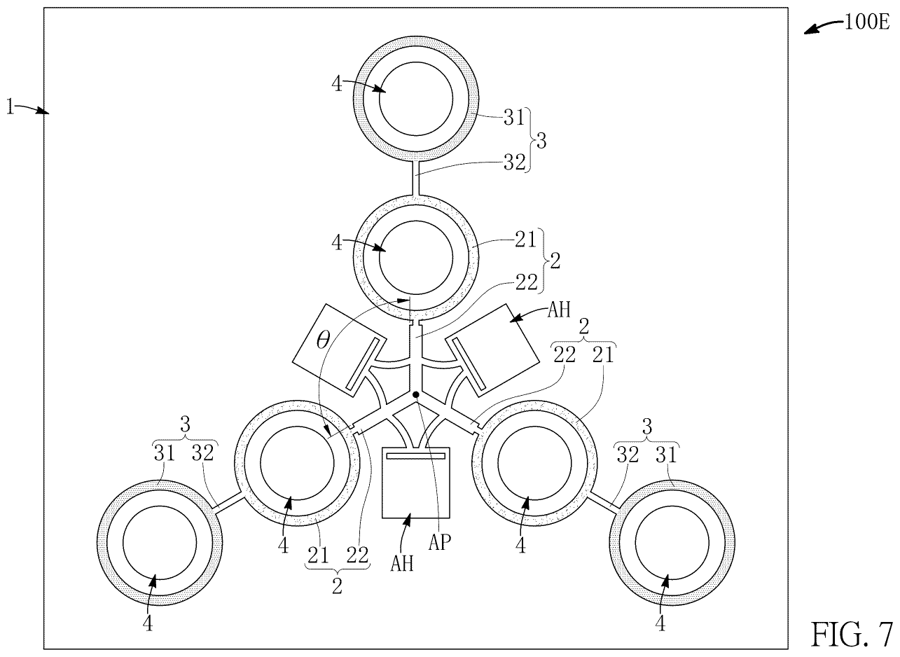

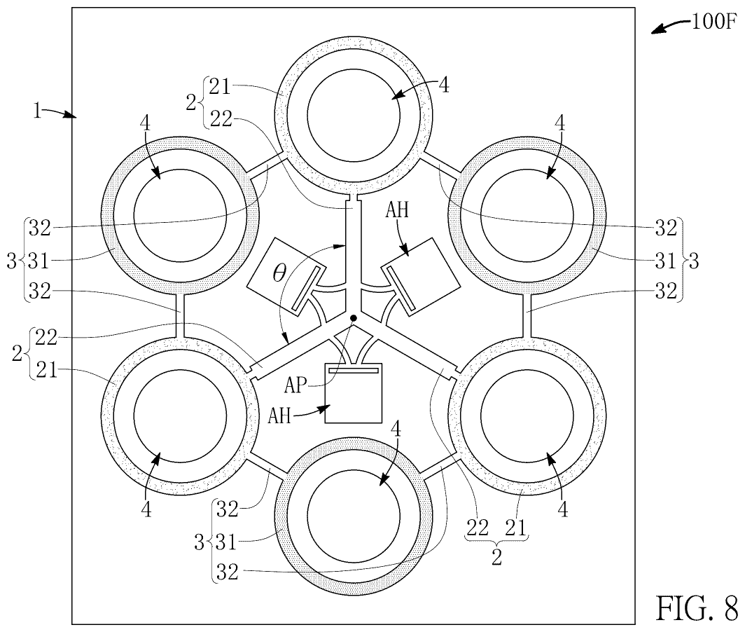

From another perspective, one end of each of the first coupling segments 22 is connected to the node AP, and the first coupling segments 22 are in a radial configuration with the node AP as a center (e.g., FIG. 1, FIG. 3, FIG. 4, FIG. 5, FIG. 7, and FIG. 8).

In practice, the first ring elements 2 are also arranged around the node AP in a radial manner. More specifically, each of a quantity of the first ring portions 21 and a quantity of the first coupling segments 22 is preferably M (where M is a positive integer greater than or equal to 2). A predetermined angle θ is between any two adjacent ones of the first ring portions 21 and the node AP, a predetermined angle θ is between any two adjacent ones of the first coupling segments 22 and the node AP, and each of the predetermined angles is 360/M.

In other words, the microelectromechanical array 100 has at least M symmetry axes SA, and the least M symmetry axes SA passes through the node AP.

In addition, a length L22 of each of the first coupling segments 22 is preferably ¼ of a wavelength corresponding to an operating frequency applicable to the microelectromechanical array 100.

Referring to FIG. 1 and FIG. 2, the second ring elements 3 are connected to the first ring elements 2, and the second ring elements 3 includes a plurality of second ring portions 31 and a plurality of second coupling segments 32. A length L32 of each of the second coupling segments 32 is preferably less than the length L22 of each of the first coupling segments 22, and each of the second coupling segments 32 enables one of the second ring portions 31 to connect to one of the first ring portions 21.

In one aspect, a quantity of the first ring portions 21, a quantity of the first coupling segments 22, a quantity of the second ring portions 31, and a quantity of the second coupling segments 32 are each M. Each of the first ring portions 21 is connected to one of the second coupling segments 32 and one of the first coupling segments 22, and each of the second ring portions 31 is connected to one of the first ring portions 21 through one of the second coupling segments 32. In the present aspect, the second ring elements 3 are also arranged in a radial configuration or are rotationally symmetrical with the node AP as the center.

For example, in the microelectromechanical array 100B of FIG. 3, when M is 4, four first ring portions 21, four first coupling segments 22, four second ring portions 31, and four second coupling segments 32 are arranged in a generally cross-shaped configuration with the node AP at the center. In the microelectromechanical array 100C of FIG. 4, the four first ring portions 21, the four first coupling segments 22, the four second ring portions 31, and the four second coupling segments 32 are arranged in a configuration that has a four-fold rotational symmetry relative to the node AP. It should be noted that M may also be an odd number. For example, as shown in FIG. 7, the microelectromechanical array 100E includes three first ring portions 21, three first coupling segments 22, three second ring portions 31, and three second coupling segments 32.

In yet another aspect, a quantity of the second ring portions 31 is M, and a quantity of the second coupling segments 32 is 2M.

Each of the first ring portions 21 is connected to two of the second coupling segments 32 and one of the first coupling segments 22, and each of the second ring portions 31 is connected to two of the first ring portions 21 via two of the second coupling segments 32.

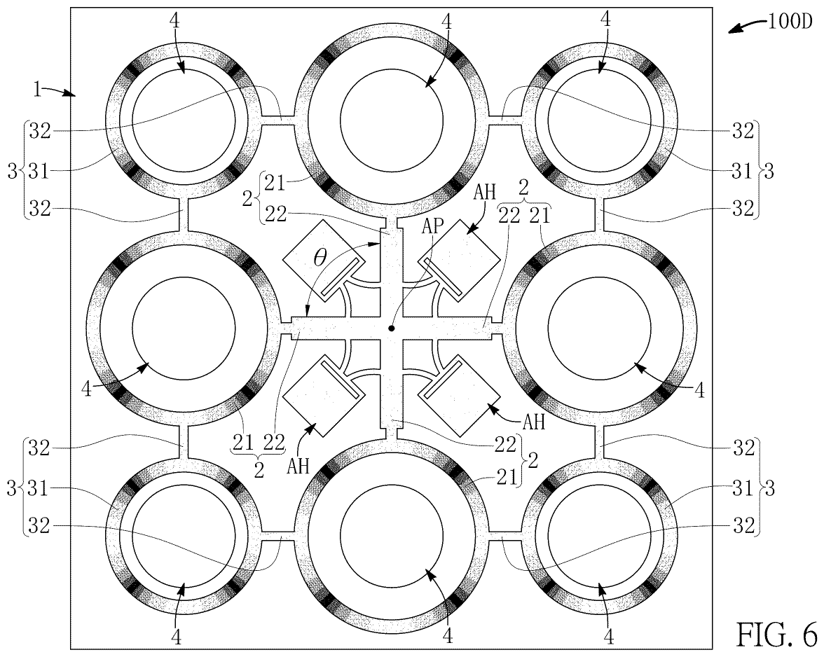

For example, as shown in FIG. 5 and FIG. 6, in the microelectromechanical array 100D, when M is 4, the four first coupling segments 22 are arranged in a substantially cross-shaped configuration with the node AP at the center. Each of the first coupling segments 22 is connected to one of the first ring portions 21. Additionally, two sides of each of the first ring portions 21 are connected to two parallel ones of the second coupling segments 32, so that the two adjacent ones of the second coupling segments 32 can be connected to one of the second ring portions 31. In the present aspect, the four first ring portions 21, the four first coupling segments 22, the four second ring portions 31, and the eight second coupling segments 32 can be arranged in a closed checkerboard shape.

It should be noted that M can also be an odd number. For example, as shown in FIG. 8, the microelectromechanical array 100F includes three first ring portions 21, three first coupling segments 22, three second ring portions 31, and six second coupling segments 32.

In practice, the quantity of the second ring elements 3 matches the quantity of the first ring elements 2, so that each of the second ring elements 3 can pair with one of the first ring elements 2 to form a differential pair. In other words, under a concept that “the quantity of the second ring elements 3 matches the quantity of the first ring elements 2,” the quantity of the first ring elements 2 and the quantity of the second ring elements 3 can be increased according to practical requirements, so that the microelectromechanical array can be expanded.

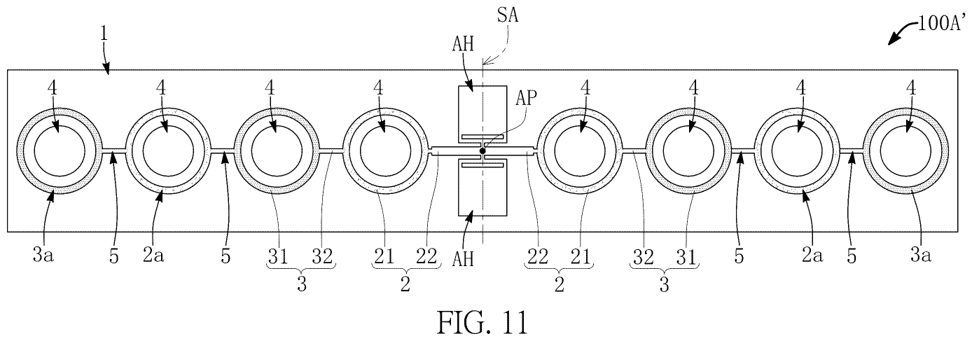

More specifically, as shown in FIG. 11 to FIG. 14, each of the microelectromechanical arrays 100A′ to 100D′ further includes a plurality of first amplified ring elements 2a, a plurality of second amplified ring elements 3a, and a plurality of amplified coupling segments 5. A structure of each of the amplified coupling segment 5 is same as that of each of the second coupling segments 32, a structure of each of the first amplified ring elements 2a is same as that of each of the first ring portions 21, and each of the first amplified ring elements 2a has the first phase. A structure of each of the second amplified ring elements 3a is same as that of the second ring portion 31, and each of the second amplified ring elements 3a has the second phase.

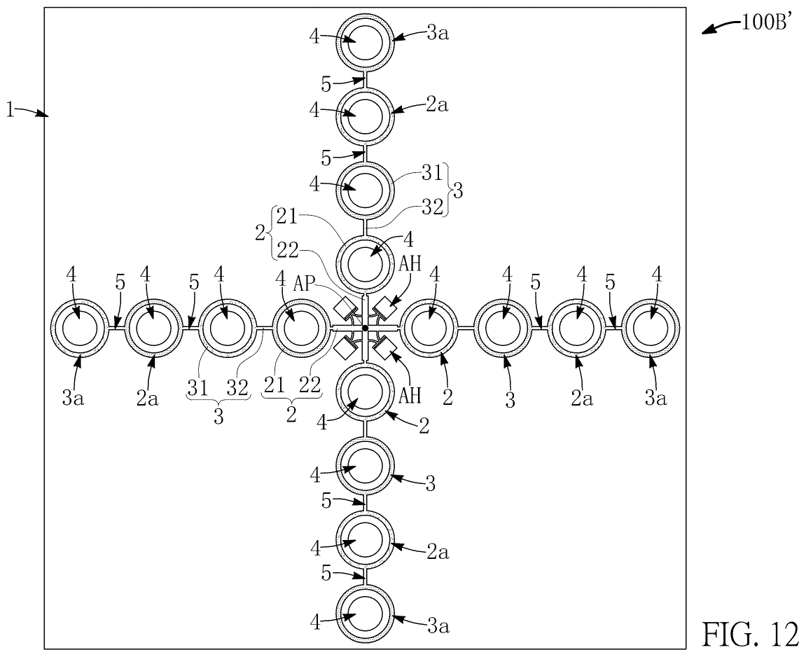

Referring to FIG. 11 and FIG. 12, some of the first amplified ring elements 2a are each connected to one of the second ring portions 31 via one of the amplified coupling segments 5. Each of the second amplified ring elements 3a is connected to one of the first amplified ring element 2a through one of the amplified coupling segments 5.

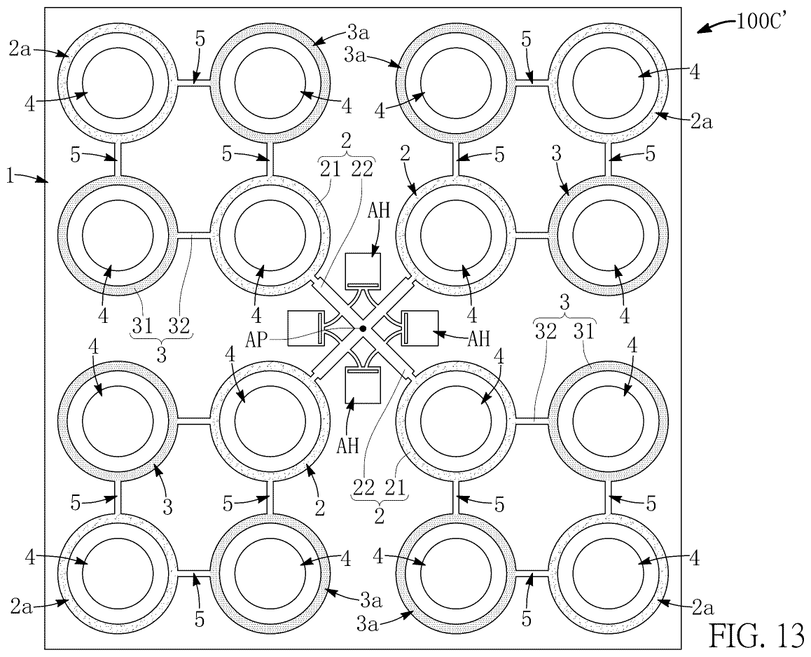

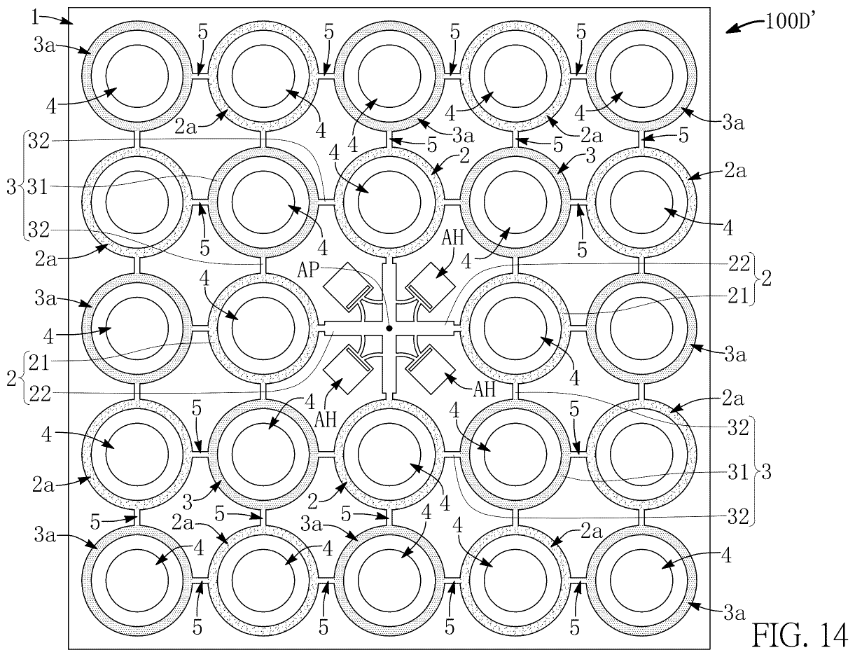

Moreover, referring to FIG. 13 and FIG. 14, in some embodiments, each of the first amplified ring elements 2a is connected to one of the second ring portions 31 through one of the amplified coupling segments 5. Each of the second amplified ring elements 3a is connected to at least two of the first amplified ring elements 2a, or one of the first amplified ring elements 2a and one of the first ring portions 21 through at least two of the amplified coupling segments 5.

Referring to FIG. 1 and FIG. 2, the electrodes 4 are disposed on the substrate 1, and each of the electrodes 4 is surrounded by any of the first ring portions 21 or any of the second ring portions 31, without coming in contact therewith. In other words, the quantity of the electrodes is a sum of the quantity of first ring portions 21 and the quantity of second ring portions 31.

In addition, each of the electrodes 4 corresponding to the first ring portion 21 can receive or send a first signal, so that the first ring portion 21 has a first phase. Each of the electrodes 4 corresponding to the second ring portion 31 can receive or send a second signal, so that the second ring portion 31 has a second phase opposite to the first phase. Accordingly, one of the first ring portions 21 and one of the second ring portions 31 adjacent to each other can form the differential pair, so that the first ring portions 21 and the second ring portions 31 can perform expansion and contraction movements.

For example, as shown in FIG. 2 and FIG. 6, when the first ring portions 21 perform an expansion action, the second ring portions 31 perform a contraction action, so that each of the second ring portions 31 is close to the electrode 4. On the contrary, when the first ring portions 21 perform a contraction action, the second ring portions 31 perform an expansion action, so that each of the second ring portions 31 is moved away from the electrode 4.

FIG. 2 and FIG. 6 are a schematic partially planar view showing the first ring portions 21 and the second ring portions 31 performing expansion and contraction movements. The higher the point density in the figure, the greater the deformation. Conversely, the lower the point density, the smaller the deformation.

It should be noted that in FIG. 2 and FIG. 6, the shapes of the first ring portions 21 and second ring portions 31, which perform expansion and contraction movements, are presented as circles for easier recognition, but the present disclosure is not limited thereto.

### Second Embodiment

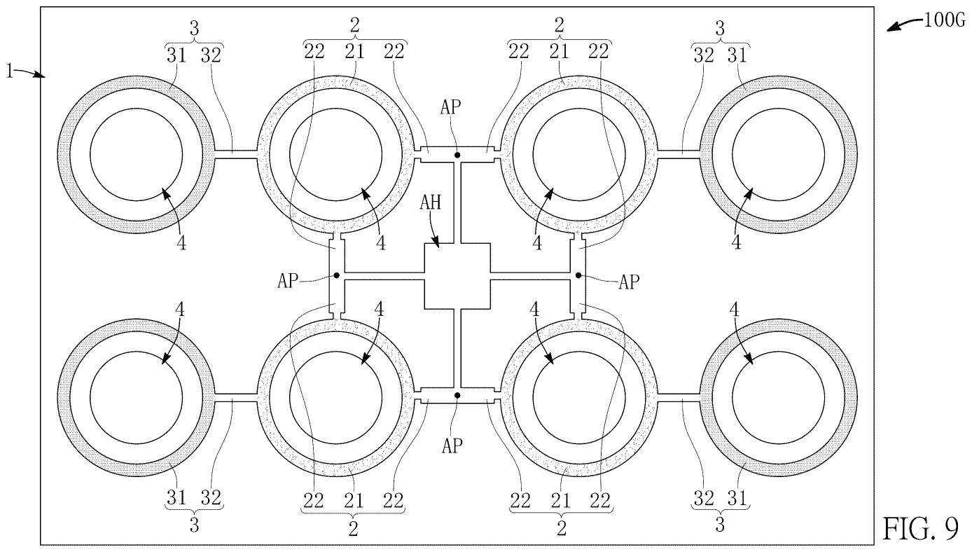

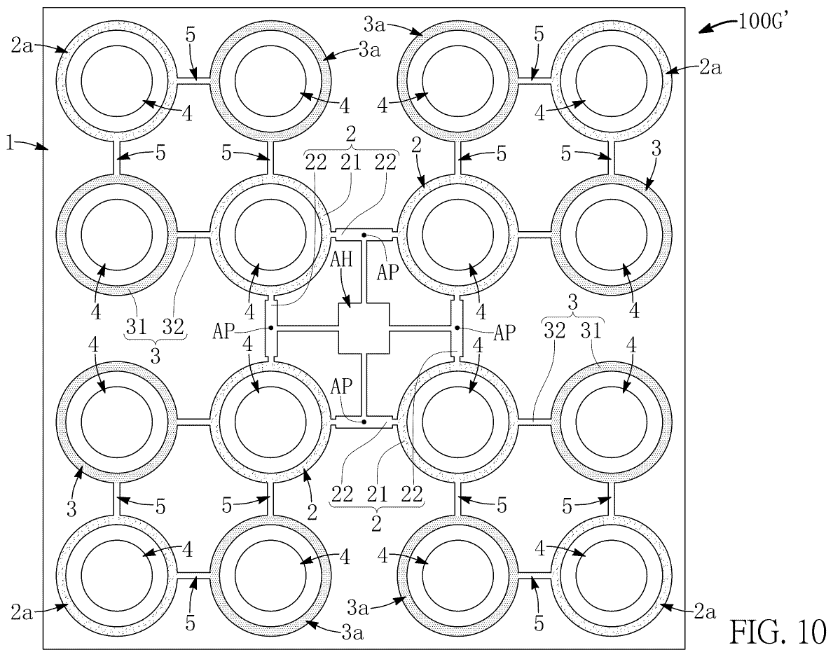

Referring to FIG. 9 and FIG. 10, the present embodiment is similar to the first embodiment, and the similarities between the present embodiment and the first embodiment will not be repeated herein. The difference between the present embodiment and the first embodiment mainly resides in that each of the first coupling segments 22 is connected to one of the first ring portions 21, so as to have a node AP. That is to say, the microelectromechanical array 100 in the present embodiment has a plurality of nodes AP.

Specifically, any two adjacent ones of the first coupling segments 22 jointly connect one of the nodes AP, any two adjacent ones of the first coupling segments 22 are connected to one of the first ring portions 21, and the nodes AP, the first coupling segments 22, and the first ring portions 21 cooperate to encircle a closed area.

Naturally, in practice, under a concept that “the quantity of the second ring elements 3 matches the quantity of the first ring elements 2,” the quantity of the first ring elements 2 and the quantity of the second ring elements 3 can be increased according to practical requirements, so that the microelectromechanical array can be expanded. For example, when the microelectromechanical array 100G shown in FIG. 9 is expanded, the microelectromechanical array 100G′ is as shown in FIG. 10.

### Beneficial Effects of the Embodiments

In conclusion, in the microelectromechanical array provided by the present disclosure, by virtue of “the first coupling segments being connected to the first ring portions, so as to jointly have a node, and each of the first ring portions having a first phase,” and “the second ring portions being connected to the first ring portions through the second coupling segments, and each of the second ring portions having a second phase that is opposite to the first phase,” the microelectromechanical array can easily calculate the capacitances of each of the first ring elements and the second ring elements, so as to allow the microelectromechanical array to be easily fabricated.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A microelectromechanical array, comprising:
a substrate including a plurality of anchor pieces;
a plurality of first ring elements disposed on the anchor pieces, wherein the first ring elements are spaced apart from the substrate, and include a plurality of first ring portions and a plurality of first coupling segments, wherein the first coupling segments are connected to the first ring portions, so as to jointly have a node, and wherein each of the first ring portions has a first phase;
a plurality of second ring elements including a plurality of second ring portions and a plurality of second coupling segments, wherein the second ring portions are connected to the first ring portions through the second coupling segments, and each of the second ring portions has a second phase that is opposite to the first phase; and
a plurality of electrodes disposed on the substrate, wherein each of the electrodes is surrounded by any of the first ring portions or any of the second ring portions, without coming in contact therewith.

2. The microelectromechanical array according to claim 1, wherein a quantity of the first ring portions is M, and M is a positive integer greater than or equal to 2; wherein a predetermined angle is between any two adjacent ones of the first ring portions and the node, and the predetermined angle is 360/M.

3. The microelectromechanical array according to claim 1, further comprising at least M symmetry axes, wherein each of the M symmetry axes passes through the node.

4. The microelectromechanical array according to claim 1, wherein the microelectromechanical array is suitable for an operating frequency, and a length of each of the first coupling segments is ¼ of a wavelength corresponding to the operating frequency.

5. The microelectromechanical array according to claim 4, wherein a length of each of the second coupling segments is less than the length of each of the first coupling segments.

6. The microelectromechanical array according to claim 1, wherein a quantity of the first ring portions, a quantity of the first coupling segments, and a quantity of the second ring portions are each M in number, a quantity of the second coupling segments is 2M, and M is a positive integer greater than or equal to 2; wherein each of the first ring portion is connected to two of the second coupling segments and one of the first coupling segments, and each of the second ring portions is connected to two of the first ring portions through two of the second coupling segments.

7. The microelectromechanical array according to claim 1, wherein a quantity of the first ring portions, a quantity of the first coupling segments, a quantity of the second ring portions, and a quantity of the second coupling segments are each M in number, and M is a positive integer greater than or equal to 2; wherein each of the first ring portions is connected to one of the second coupling segments and one of the first coupling segments, and each of the second ring portions is connected to one of the first ring portions through one of the second coupling segments.

8. The microelectromechanical array according to claim 1, further comprising a plurality of first amplified ring elements, a plurality of second amplified ring elements, and a plurality of amplified coupling segments, wherein a structure of each of the amplified coupling segments is same as a structure of each of the second coupling segments, a structure of each of the first amplified ring elements is same as a structure of each of the first ring portions, and each of the first amplified ring elements has the first phase;
wherein a structure of each of the second amplified ring elements is same as a structure of each of the second ring portion, and each of the second amplified ring elements has the second phase; and wherein each of the first amplified ring elements is connected to one of the second ring portions through one of the amplified coupling segments, and each of the second amplified ring elements is connected to one of the first amplified ring elements through one of the amplified coupling segments.

9. The microelectromechanical array according to claim 6, further comprising a plurality of first amplified ring elements, a plurality of second amplified ring elements, and a plurality of amplified coupling segments; wherein a structure of each of the amplified coupling segments is same as a structure of each of the second coupling segments, a structure of each of the first amplified ring elements is same as a structure of each of the first ring portions, and each of the first amplified ring elements has the first phase;
wherein a structure of each of the second amplified ring elements is same as a structure of each of the second ring portions, and each of the second amplified ring elements has the second phase; wherein each of the first amplified ring elements is connected to one of the second ring portions through one of the amplified coupling segments, and each of the second amplified ring elements is connected to at least two of the first amplified ring elements, or one of the first amplified ring elements and one of the first ring portions through at least two of the amplified coupling segments.

10. The microelectromechanical array according to claim 1, wherein a quantity of the second ring elements is equal to a quantity of the first ring elements.

11. A microelectromechanical array, comprising:
a substrate including a plurality of anchor pieces;
a plurality of first ring elements disposed on the anchor pieces, wherein the first ring elements are spaced apart from the substrate, and include a plurality of first ring portions and a plurality of first coupling segments, wherein each of the first coupling segments is connected to one of the first ring portions, so as to jointly have a node, and wherein each of the first ring portions has a first phase;
a plurality of second ring elements including a plurality of second ring portions and a plurality of second coupling segments, wherein the second ring portions are connected to the first ring portions through the second coupling segments, and each of the second ring portions has a second phase that is opposite to the first phase; and
a plurality of electrodes disposed on the substrate, wherein each of the electrodes is surrounded by any of the first ring portions or any of the second ring portions, without coming in contact therewith.

12. The microelectromechanical array according to claim 11, wherein the microelectromechanical array is suitable for an operating frequency, and a length of each of the first coupling segments is ¼ of a wavelength corresponding to the operating frequency.

13. The microelectromechanical array according to claim 11, wherein a length of each of the second coupling segments is less than the length of each of the first coupling segments.

14. The microelectromechanical array according to claim 11, further comprising a plurality of first amplified ring elements, a plurality of second amplified ring elements, and a plurality of amplified coupling segments, wherein a structure of each of the amplified coupling segments is same as a structure of each of the second coupling segments, a structure of each of the first amplified ring elements is same as a structure of each of the first ring portions, and each of the first amplified ring elements has the first phase; wherein a structure of each of the second amplified ring elements is same as a structure of each of the second ring portion, and each of the second amplified ring elements has the second phase; and wherein each of the first amplified ring elements is connected to one of the second ring portions through one of the amplified coupling segments, and each of the second amplified ring elements is connected to one of the first amplified ring elements through one of the amplified coupling segments.

15. The microelectromechanical array according to claim 11, further comprising a plurality of first amplified ring elements, a plurality of second amplified ring elements, and a plurality of amplified coupling segments; wherein a structure of each of the amplified coupling segments is same as a structure of each of the second coupling segments, a structure of each of the first amplified ring elements is same as a structure of each of the first ring portions, and each of the first amplified ring elements has the first phase; wherein a structure of each of the second amplified ring elements is same as a structure of each of the second ring portions, and each of the second amplified ring elements has the second phase; wherein each of the first amplified ring elements is connected to one of the second ring portions through one of the amplified coupling segments, and each of the second amplified ring elements is connected to at least two of the first amplified ring elements, or one of the first amplified ring elements and one of the first ring portions through at least two of the amplified coupling segments.
